(19) United States
(12) Patent Application Publication
(10) Pub. No.: US 2026/0013224 A1
(43) Pub. Date: Jan. 8, 2026

(54) INTEGRATED DEVICES AND METHOD FOR MANUFACTURING SAME

(71) Applicant: Microchip Technology Incorporated, Chandler, AZ (US)

(72) Inventors: Shesh Mani Pandey, Gilbert, AZ (US); Bomy Chen, Newark, CA (US); Philippe Deval, Lutry (CH); Steve Nagel, Chandler, AZ (US)

(73) Assignee: Microchip Technology Incorporated, Chandler, AZ (US)

(21) Appl. No.: 19/035,779

(22) Filed: Jan. 23, 2025

Related U.S. Application Data
(60) Provisional application No. 63/667,440, filed on Jul. 3, 2024.

(51) Int. Cl. H10D 86/00; H01L 21/762; H10D 86/01

(52) U.S. Cl. CPC H10D 86/201; H01L 21/76267; H01L 21/76275; H01L 21/76283; H10D 86/01

(57) ABSTRACT

An integrated device comprising a buried oxide layer within a trench within a top surface of a substrate. A silicon layer formed over the buried oxide layer and the top surface of the substrate.

### CROSS-REFERENCE TO RELATED APPLICATION

The present application claims priority to U.S. Provisional Patent Application No. 63/667,440, filed on Jul. 3, 2024, the contents of which are hereby incorporated by reference in their entirety.

### TECHNICAL FIELD

The present disclosure relates generally to semiconductor devices, and more specifically to integrated semiconductor devices and methods for manufacturing same for lower parasitic inductive noise between the integrated devices and better heat transfer draining down to the substrate.

### SUMMARY

According to an aspect of one or more examples, there is provided an integrated device that may include a substrate having a top surface with a trench in the top surface, a buried oxide layer formed within the trench in the top surface of the substrate, and a silicon layer formed over the buried oxide layer and the top surface of the substrate. The substrate may comprise silicon. The buried oxide layer may comprise silicon dioxide. The buried oxide layer may have a thickness between 0.5 micrometers and 5 micrometers. The silicon layer may comprise epitaxially grown silicon. A silicon wafer may be bonded to the silicon layer. The silicon layer may have a thickness between 20 micrometers and 50 micrometers.

According to an aspect of one or more examples, there is provided a method of manufacturing an integrated device. The method may include providing a substrate having a top surface, forming a buried oxide layer over the top surface of the substrate, forming a silicon on insulator layer over the buried oxide layer, exposing a portion of the top surface of the substrate by forming a trench through the silicon on insulator layer and through the buried oxide layer, epitaxially growing a silicon layer over the exposed portion of the top surface of the substrate within the trench, and chemically mechanically polishing the epitaxially grown silicon layer. The substrate may comprise silicon. The buried oxide layer may comprise silicon dioxide. The buried oxide layer may have a thickness between 0.5 micrometers and 5 micrometers.

According to an aspect of one or more examples, there is provided a method of manufacturing an integrated device. The method may include providing a substrate having a top surface, forming a trench in the top surface of the substrate, forming a buried oxide layer within the trench in the top surface of the substrate, epitaxially growing a silicon layer over the buried oxide layer and the top surface of the substrate, epitaxially growing an additional silicon layer over the silicon layer, chemically mechanically polishing the epitaxially grown silicon layers, and epitaxially growing another silicon layer over the chemically mechanically polished silicon layers. The substrate may comprise silicon. The buried oxide layer may comprise silicon dioxide. The buried oxide layer may have a thickness between 0.5 micrometers and 5 micrometers. The chemically mechanically polished silicon layers may have a combined thickness between 20 micrometers and 50 micrometers.

According to an aspect of one or more examples, there is provided a method of manufacturing an integrated device. The method may include providing a substrate having a top surface, forming a trench in the top surface of the substrate, forming a buried oxide layer within the trench in the top surface of the substrate, epitaxially growing a silicon layer over the buried oxide layer and the top surface of the substrate, epitaxially growing an additional silicon layer over the silicon layer, chemically mechanically polishing the epitaxially grown silicon layers, and bonding a silicon wafer to the chemically mechanically polished silicon layers. The substrate may comprise silicon. The buried oxide layer may comprise silicon dioxide. The buried oxide layer may have a thickness between 0.5 micrometers and 5 micrometers.

### BRIEF DESCRIPTION OF DRAWINGS

FIG. 1 shows an illustration of an integrated device according to one or more examples.

FIG. 2A is a cross sectional view of some of the steps in a method of manufacturing an integrated device according to one or more examples.

FIG. 2B is a cross sectional view of some of the steps in a method of manufacturing an integrated device according to one or more examples.

FIG. 2C is a cross sectional view of some of the steps in a method of manufacturing an integrated device according to one or more examples.

FIG. 2D is a cross sectional view of some of the steps in a method of manufacturing an integrated device according to one or more examples.

FIG. 3A is a cross sectional view of some of the steps in a method of manufacturing an integrated device according to one or more examples.

FIG. 3B is a cross sectional view of some of the steps in a method of manufacturing an integrated device according to one or more examples.

FIG. 3C is a cross sectional view of some of the steps in a method of manufacturing an integrated device according to one or more examples.

FIG. 3D is a cross sectional view of some of the steps in a method of manufacturing an integrated device according to one or more examples.

FIG. 3E is a cross sectional view of some of the steps in a method of manufacturing an integrated device according to one or more examples.

FIG. 4A is a cross sectional view of some of the steps in a method of manufacturing an integrated device according to one or more examples.

FIG. 4B is a cross sectional view of some of the steps in a method of manufacturing an integrated device according to one or more examples.

FIG. 4C is a cross sectional view of some of the steps in a method of manufacturing an integrated device according to one or more examples.

FIG. 4D is a cross sectional view of some of the steps in a method of manufacturing an integrated device according to one or more examples.

FIG. 4E is a cross sectional view of some of the steps in a method of manufacturing an integrated device according to one or more examples.

FIG. 4F is a cross sectional view of some of the steps in a method of manufacturing an integrated device according to one or more examples.

### DETAILED DESCRIPTION OF VARIOUS EXAMPLES

Reference will now be made in detail to the following various examples, which are illustrated in the accompanying drawings, wherein like reference numerals refer to like elements throughout. The following examples may be in various forms without being limited to the examples set forth herein.

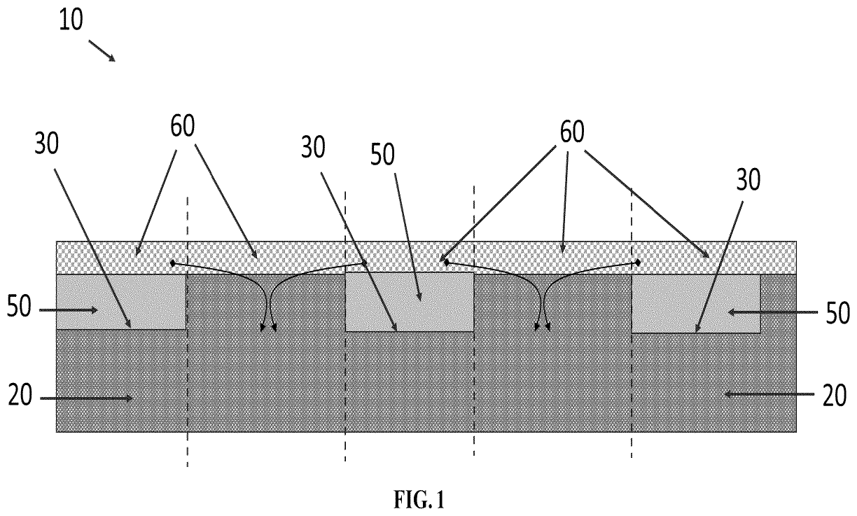

FIG. 1 shows an illustration of an integrated device 10 according to one or more examples. Integrated device 10 may represent lateral complementary metal oxide semiconductor (CMOS) and vertical high voltage metal oxide semiconductor field effect transistor (MOSFET) and insulated gate bipolar transistor (IGBT) in a silicon on insulator (SOI) substrate 20, without limitation. As shown in FIG. 1, the substrate 20 may have a buried oxide layer 50 formed within a trench 30 in a top surface of the substrate 20. A silicon layer 60 may be epitaxially formed over the buried oxide layer 50 and the top surface of the substrate 20. In one or more examples, a silicon wafer may be bonded to the epitaxially grown silicon layer 60. As shown in FIG. 1, the substrate 20 with the buried oxide layer 50 within a trench 30 in the top surface of the substrate 20 with the silicon layer 60 formed over the buried oxide layer 50 may form an SOI CMOS device that may be adjacent to a vertical MOSFET formed on the same substrate 20. This integrated device 10 allows for a lower parasitic inductive noise between the SOI CMOS and the vertical MOSFET since no wire bonding is required between these two devices. In addition, the arrangement of the SOI CMOS and the vertical MOSFET on the same substrate 20 allows for better heat transfer draining down to the substrate 20.

The substrate 20 shown in FIG. 1 may comprise silicon. The buried oxide layer 50 may comprise silicon dioxide and may have a thickness between 0.5 micrometers and 5 micrometers. The epitaxially grown silicon layer 60 may have a thickness between 20 micrometers and 50 micrometers.

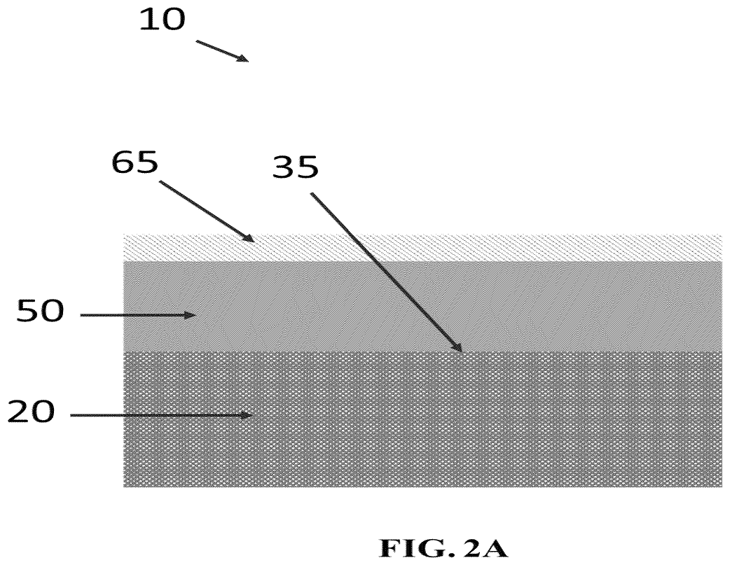

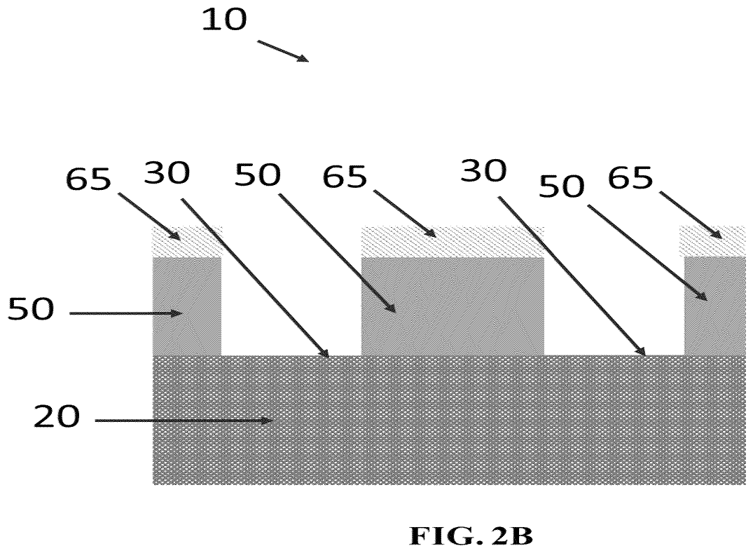

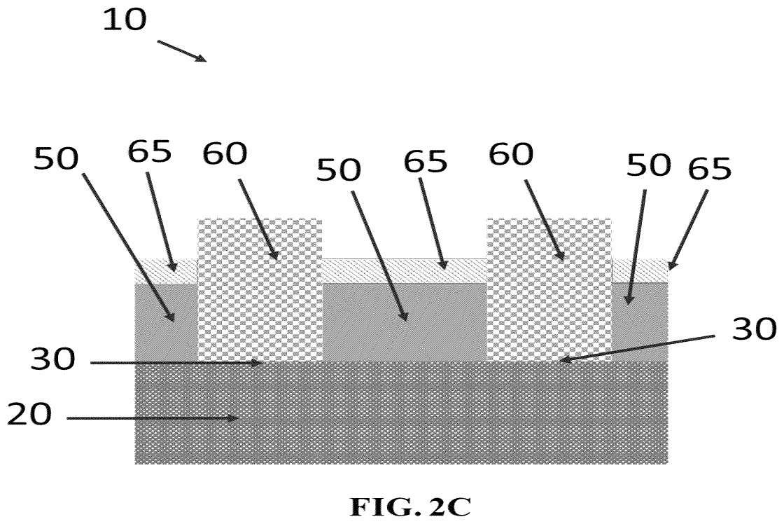

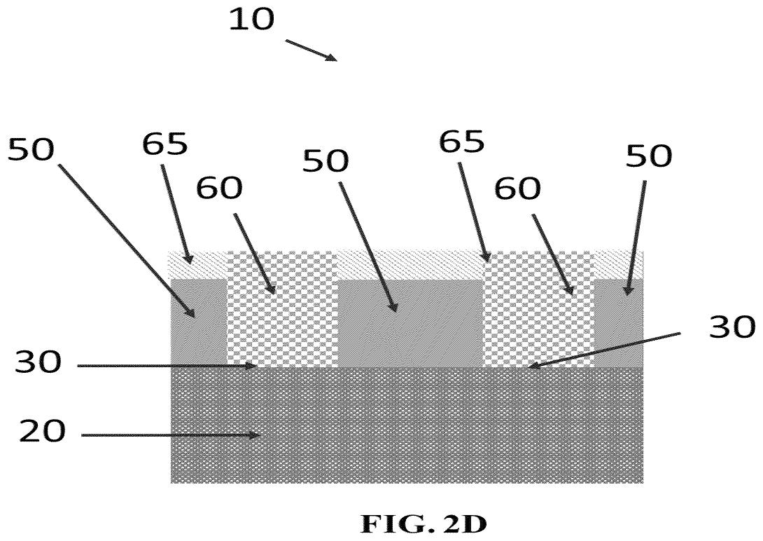

FIGS. 2A-2D show a method of manufacturing an integrated device 10 according to one or more examples. Although the example method shown in FIGS. 2A-2D include steps shown in a particular order, the steps may be performed in a different order, and may include additional steps that are not explicitly shown.

FIG. 2A is a cross sectional view of some of the steps in a method of manufacturing an integrated device 10 according to one or more examples. In FIG. 2A, the example method may include providing a silicon substrate 20. A buried oxide layer 50 may be formed over a top surface 35 of the substrate 20. The buried oxide layer 50 may comprise silicon dioxide. The buried oxide layer 50 may have a thickness between 0.5 micrometers and 5 micrometers. A silicon on insulator (SOI) layer 65 may be formed over the buried oxide layer 50.

FIG. 2B is a cross sectional view of some of the steps in a method of manufacturing an integrated device 10 according to one or more examples. FIG. 2B, the example method may include forming a trench 30 to the substrate 20 through the SOI layer 65 and the buried oxide layer 50.

FIG. 2C is a cross sectional view of some of the steps in a method of manufacturing an integrated device 10 according to one or more examples. In the method step shown in FIG. 2C, a silicon layer 60 may be epitaxially grown on an exposed portion of the substrate 20 within the trench 30.

FIG. 2D is a cross sectional view of some of the steps in a method of manufacturing an integrated device 10 according to one or more examples. In FIG. 2D, after the silicon layer 60 is formed within the trench 30 in FIG. 2C, a chemical mechanical polishing (CMP) step may be applied to the epitaxially grown silicon layer 60.

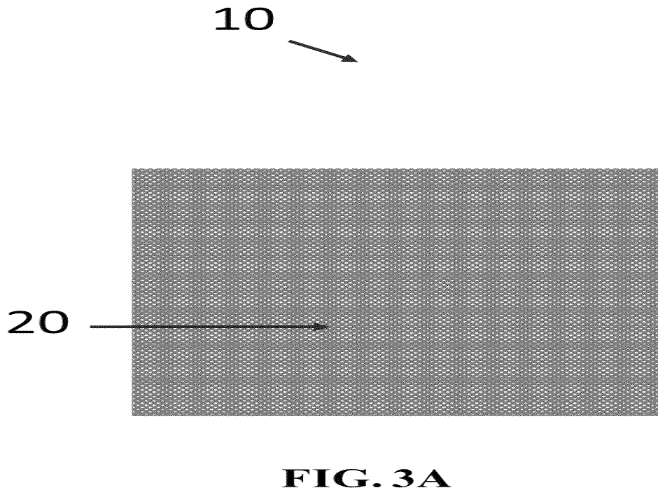

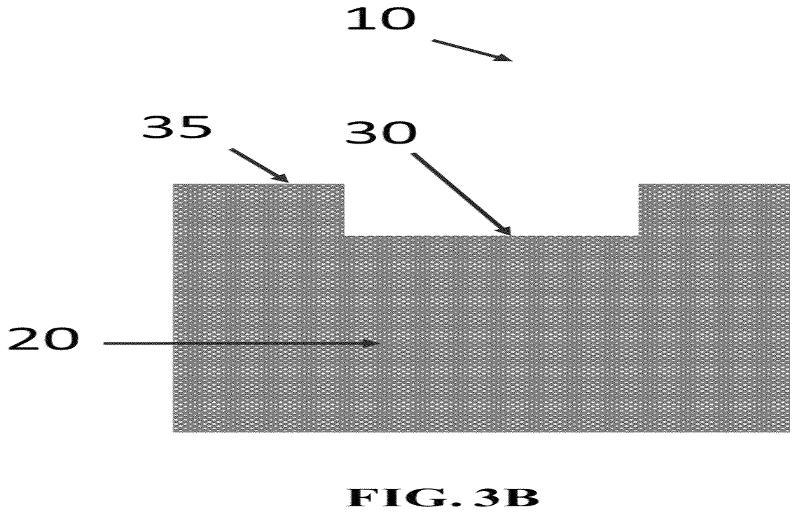

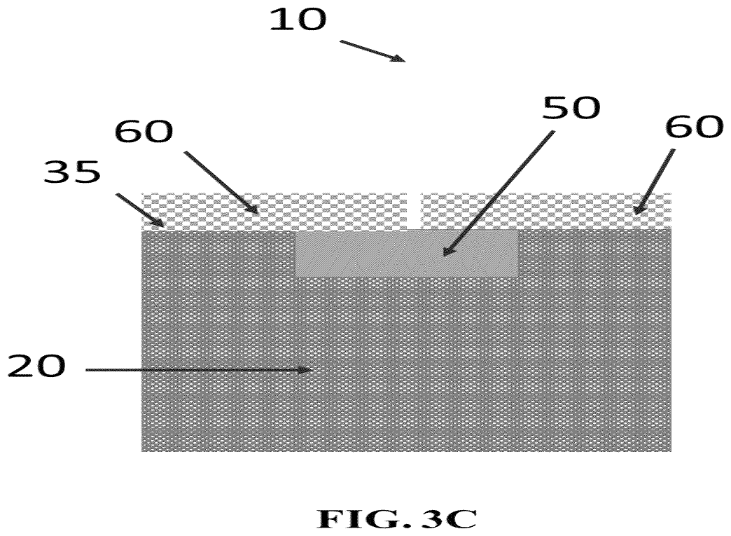

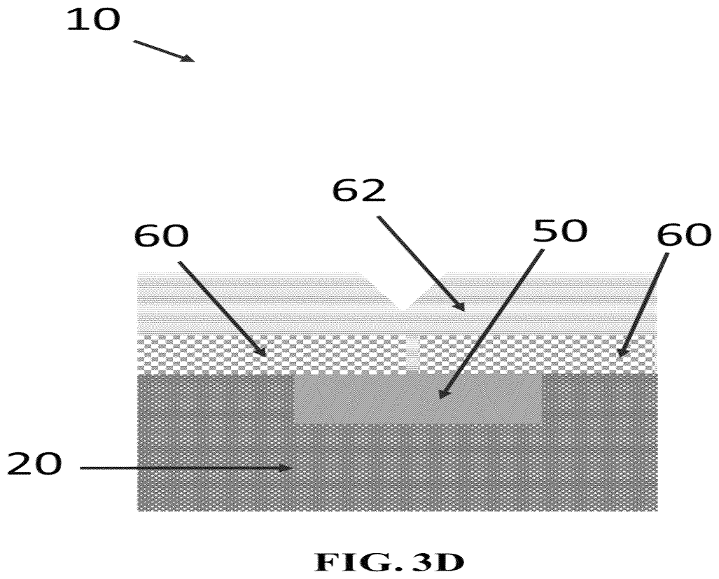

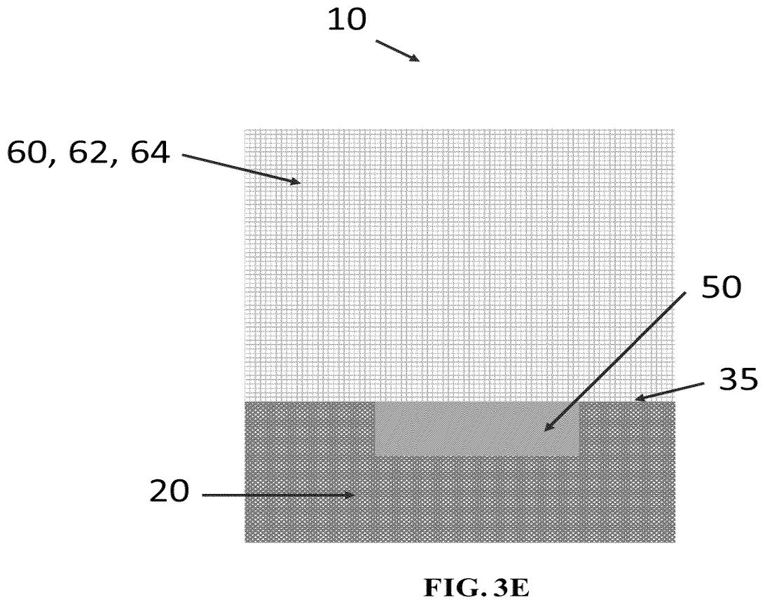

FIGS. 3A-3E show a method of manufacturing an integrated device 10 according to one or more examples. Although the example method shown in FIGS. 3A-3E include steps shown in a particular order, the steps may be performed in a different order, and may include additional steps that are not explicitly shown.

FIG. 3A is a cross sectional view of some of the steps in a method of manufacturing an integrated device 10 according to one or more examples. In FIG. 3A, the example method may include providing a silicon substrate 20.

FIG. 3B is a cross sectional view of some of the steps in a method of manufacturing an integrated device 10 according to one or more examples. FIG. 3B includes forming a shallow trench isolation (STI) 30 in a top surface 35 of the substrate 20. A buried oxide layer 50 may be formed within the STI 30 in the top surface 35 of the substrate 20. The buried oxide layer 50 may comprise silicon dioxide. The buried oxide layer 50 may have a thickness between 0.5 micrometers and 5 micrometers.

FIG. 3C is a cross sectional view of some of the steps in a method of manufacturing an integrated device 10 according to one or more examples. In the method step shown in FIG. 3C, a silicon layer 60 may be epitaxially grown over the buried oxide layer 50 and the top surface 35 of the substrate 20.

FIG. 3D is a cross sectional view of some of the steps in a method of manufacturing an integrated device 10 according to one or more examples. In FIG. 3D, after the silicon layer 60 is formed in FIG. 3C, an additional silicon layer 62 may be epitaxially grown over the silicon layer 60.

FIG. 3E is a cross sectional view of some of the steps in a method of manufacturing an integrated device 10 according to one or more examples. FIG. 3E, after a chemical mechanical polishing (CMP) step, another silicon layer 64 may be epitaxially grown so that the epitaxially grown silicon layers 60, 62, 64 may have a combined thickness between 20 micrometers and 50 micrometers. The epitaxially grown silicon layers 60, 62, 64 are over the top surface 35 of the substrate 20 and the buried oxide layer 50 which results in the final integrated device 10.

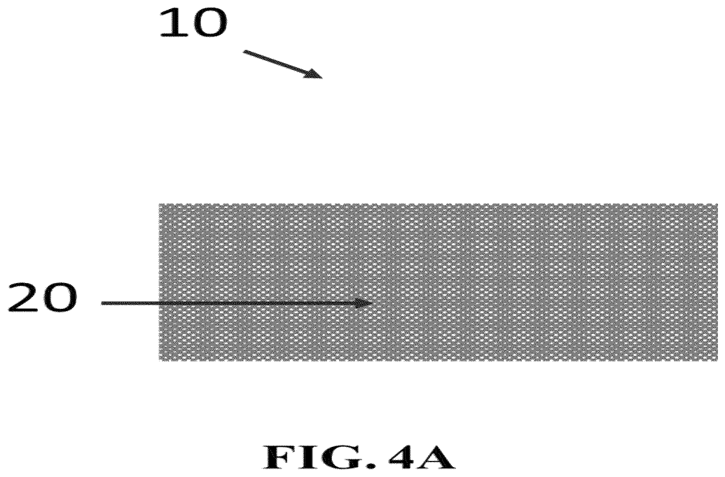

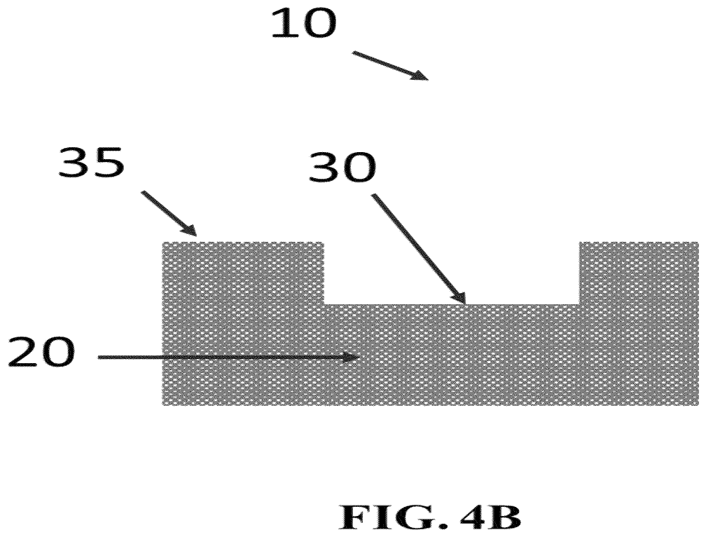

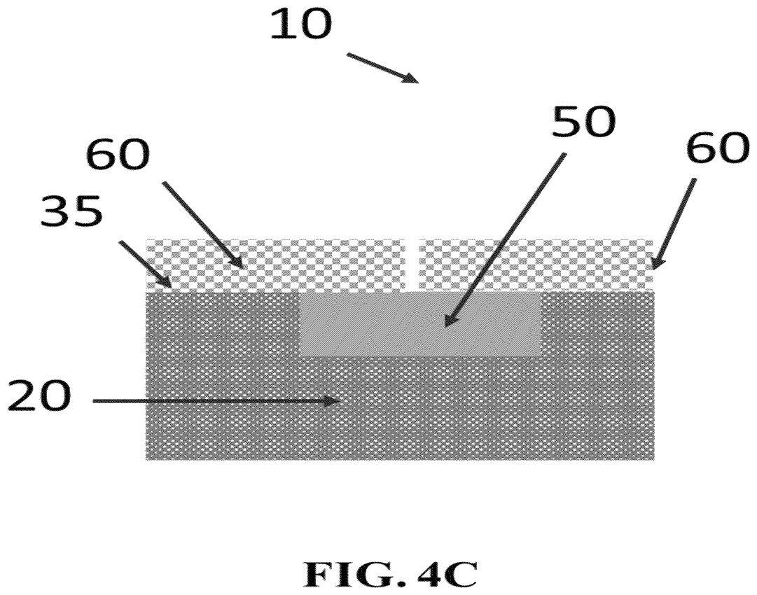

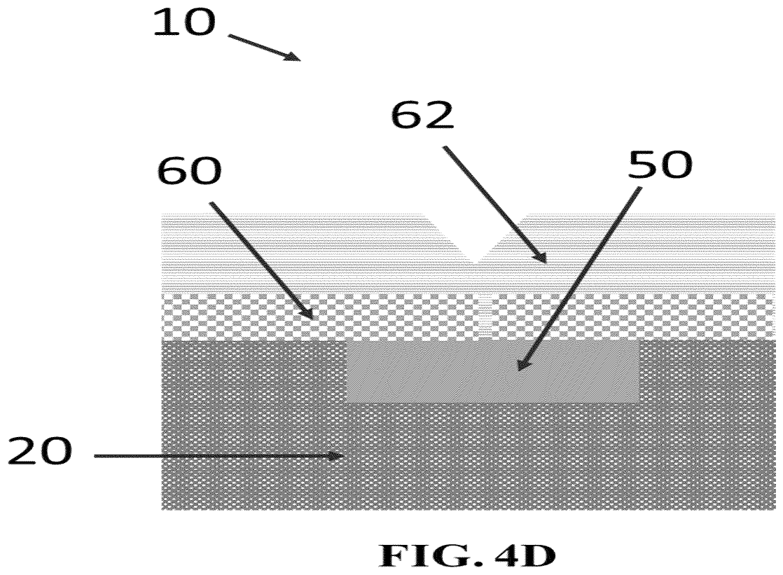

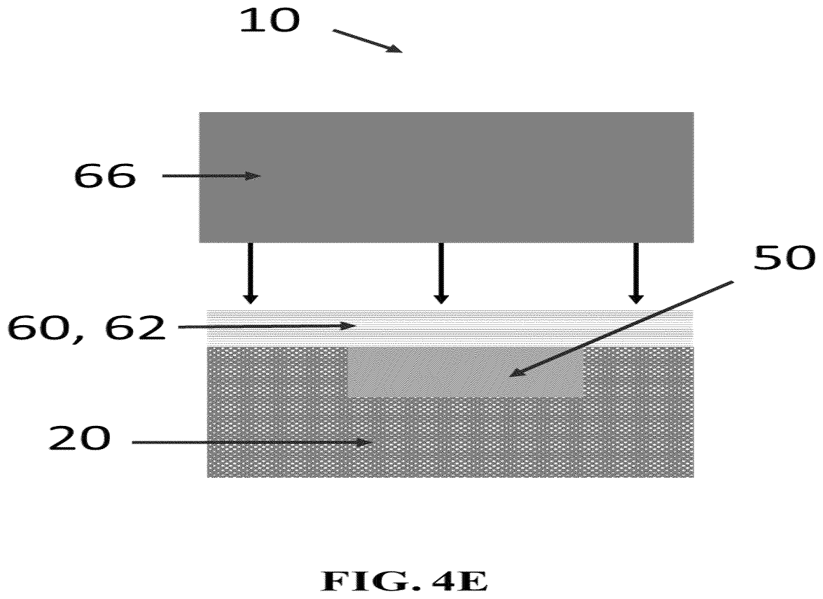

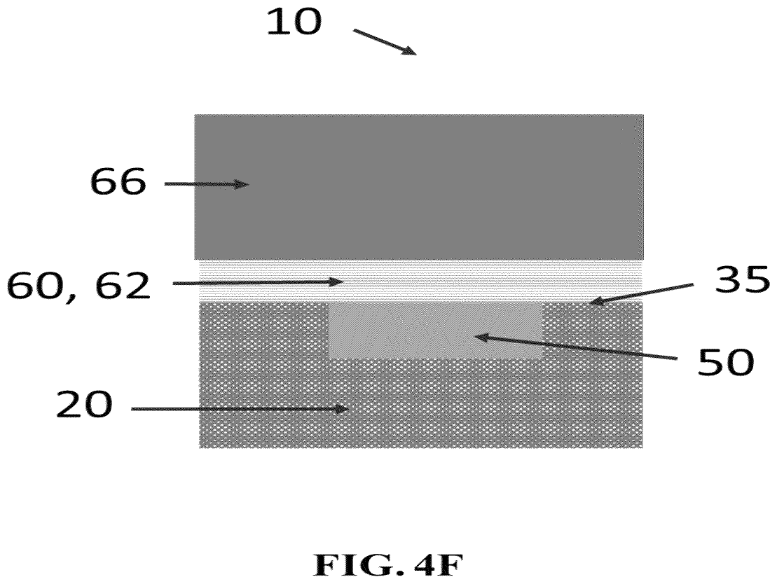

FIGS. 4A-4F show a method of manufacturing an integrated device 10 according to one or more examples. Although the example method shown in FIGS. 4A-4F include steps shown in a particular order, the steps may be performed in a different order, and may include additional steps that are not explicitly shown.

FIG. 4A is a cross sectional view of some of the steps in a method of manufacturing an integrated device 10 according to one or more examples. In FIG. 4A, the example method may include providing a silicon substrate 20.

FIG. 4B is a cross sectional view of some of the steps in a method of manufacturing an integrated device 10 according to one or more examples. FIG. 4B includes forming a shallow trench isolation (STI) 30 in a top surface 35 of the substrate 20. A buried oxide layer 50 may be formed within the STI 30 in the top surface 35 of the substrate 20. The buried oxide layer 50 may comprise silicon dioxide. The buried oxide layer 50 may have a thickness between 0.5 micrometers and 5 micrometers.

FIG. 4C is a cross sectional view of some of the steps in a method of manufacturing an integrated device 10 according to one or more examples. In the method step shown in FIG. 4C, a silicon layer 60 may be epitaxially grown over the buried oxide layer 50 and the top surface 35 of the substrate 20.

FIG. 4D is a cross sectional view of some of the steps in a method of manufacturing an integrated device 10 according to one or more examples. In FIG. 4D, after the silicon layer 60 is formed in FIG. 4C, an additional silicon layer 62 may be epitaxially grown over the silicon layer 60.

FIG. 4E is a cross sectional view of some of the steps in a method of manufacturing an integrated device 10 according to one or more examples. In FIG. 4E, after a chemical mechanical polishing (CMP) step, a silicon wafer 66 may be bonded to the chemically mechanically polished epitaxially grown silicon layers 60, 62.

FIG. 4F is a cross sectional view of some of the steps in a method of manufacturing an integrated device 10 according to one or more examples. FIG. 4F shows the final integrated device 10 after the silicon wafer 66 has been bonded to the chemically mechanically polished epitaxially grown silicon layers 62, 64 which are over the top surface 35 of the substrate 20 and the buried oxide layer 50.

Various examples have been disclosed herein, in connection with the above description and the drawings. It will be understood that it would be unduly repetitious to literally describe and illustrate every combination and subcombination of these examples. Accordingly, all examples may be combined in any way and/or combination, and the present specification, including the drawings, shall be construed to constitute a complete written description of all combinations and subcombinations of the examples described herein, and of the manner and process of making and using them, and shall support claims to any such combination or subcombination.

It will be appreciated by persons skilled in the art that the examples described herein are not limited to what has been particularly shown and described herein above. In addition, unless mention was made above to the contrary, it should be noted that all of the accompanying drawings are not to scale. A variety of modifications and variations are possible in light of the above teachings.

What is claimed is:

1. An integrated device comprising:
a substrate having a top surface with a trench in the top surface;
a buried oxide layer formed within the trench in the top surface of the substrate; and
a silicon layer formed over the buried oxide layer and the top surface of the substrate.

2. The integrated device of claim 1, wherein the substrate comprises silicon.

3. The integrated device of claim 1, wherein the buried oxide layer comprises silicon dioxide.

4. The integrated device of claim 1, wherein the buried oxide layer has a thickness between 0.5 micrometers and 5 micrometers.

5. The integrated device of claim 1, wherein the silicon layer comprises epitaxially grown silicon.

6. The integrated device of claim 5, comprising a silicon wafer bonded to the silicon layer.

7. The integrated device of claim 1, wherein the silicon layer has a thickness between 20 micrometers and 50 micrometers.

8. A method of manufacturing an integrated device, the method comprising:
providing a substrate having a top surface;
forming a buried oxide layer over the top surface of the substrate;
forming a silicon on insulator layer over the buried oxide layer;
exposing a portion of the top surface of the substrate by forming a trench through the silicon on insulator layer and through the buried oxide layer;
epitaxially growing a silicon layer over the exposed portion of the top surface of the substrate within the trench; and
chemically mechanically polishing the epitaxially grown silicon layer.

9. The method of claim 8, wherein the substrate comprises silicon.

10. The method of claim 8, wherein the buried oxide layer comprises silicon dioxide.

11. The method of claim 8, wherein the buried oxide layer has a thickness between 0.5 micrometers and 5 micrometers.

12. A method of manufacturing an integrated device, the method comprising:
providing a substrate having a top surface;
forming a trench in the top surface of the substrate;
forming a buried oxide layer within the trench in the top surface of the substrate;
epitaxially growing a silicon layer over the buried oxide layer and the top surface of the substrate;
epitaxially growing an additional silicon layer over the silicon layer;
chemically mechanically polishing the epitaxially grown silicon layers; and
epitaxially growing another silicon layer over the chemically mechanically polished silicon layers.

13. The method of claim 12, wherein the substrate comprises silicon.

14. The method of claim 12, wherein the buried oxide layer comprises silicon dioxide.

15. The method of claim 12, wherein the buried oxide layer has a thickness between 0.5 micrometers and 5 micrometers.

16. The method of claim 12, wherein the chemically mechanically polished silicon layers have a combined thickness between 20 micrometers and 50 micrometers.

17. A method of manufacturing an integrated device, the method comprising:
providing a substrate having a top surface;
forming a trench in the top surface of the substrate;
forming a buried oxide layer within the trench in the top surface of the substrate;
epitaxially growing a silicon layer over the buried oxide layer and the top surface of the substrate;
epitaxially growing an additional silicon layer over the silicon layer;
chemically mechanically polishing the epitaxially grown silicon layers; and
bonding a silicon wafer to the chemically mechanically polished silicon layers.

18. The method of claim 17, wherein the substrate comprises silicon.

19. The method of claim 17, wherein the buried oxide layer comprises silicon dioxide.

20. The method of claim 17, wherein the buried oxide layer has a thickness between 0.5 micrometers and 5 micrometers.
